(19) United States
(12) Patent Application Publication
(10) Pub. No.: US 2016/0298226 A1
(43) Pub. Date: Oct. 13, 2016

(54) COATING PROCESS AND DEVICE FOR PRODUCING A SELECTIVE METALIZATION OF MOTOR VEHICLE LIGHTING DEVICE AND/OR SIGNALING PARTS

(71) Applicant: VALEO VISION, Bobigny Cedex (FR)

(72) Inventors: Erwan Faoucher, Nantes (FR); Julien Corbineau, Pont Saint Martin (FR); Michel Hermitte, Angers (FR)

(21) Appl. No.: 15/036,185

(22) PCT Filed: Nov. 28, 2014
(86) PCT No.: PCT/EP2014/075926

§ 371 Date: May 12, 2016

(30) Foreign Application Priority Data
Nov. 28, 2013 (FR) 1361812

(51) Int. Cl. C23C 14/04; C23C 14/34; C23C 14/24

(52) U.S. Cl. CPC C23C 14/042; C23C 14/24; C23C 14/34; B60Q 1/0005

(57) ABSTRACT

A coating process and device for producing a selective metalization, comprising the deposition of a metalization layer, on a motor vehicle lighting and/or signaling device part comprises an application, prior to the metalization, of a covering film to the portions intended not to be metalized, so as to protect the portions intended not to be metalized during the vacuum metalization operation and so as to bare the non-metalized portions after removal of the covering film.

### CROSS-REFERENCE TO RELATED APPLICATIONS

This application is the U.S. National Phase application of PCT Application No. PCT/EP2014/075926 filed Nov. 28, 2014, which claims priority to the French application 1361812 filed on Nov. 28, 2013, which applications are incorporated herein by reference and made a part hereof.

### BACKGROUND OF THE INVENTION

1. Field of the Invention

The invention relates to a coating process for producing a selective metalization, comprising the deposition of a metalization layer, on a motor vehicle lighting and/or signaling device part intended to comprise metalized portions and non-metalized portions.

The invention also relates to a coating device for producing a selective metalization, comprising the deposition of a metalization layer, on a motor vehicle lighting and/or signaling device part intended to comprise metalized portions and non-metalized portions.

The invention finally relates to a motor vehicle lighting and/or signaling device part comprising metalized portions and non-metalized portions obtained by implementation of a process according to the invention or by means of a device according to the invention.

2. Description of the Related Art

In the production of motor vehicle lighting and/or signaling device parts, such as headlamps or lights for motor vehicles, it is known to highlight a “metalized” zone and other non-metalized zones, so as to give a particular characteristic or aspect to the headlamps or lights.

Currently, motor vehicle headlamps or lights are produced by assembling several parts from different injection-molding molds, each part having distinctive shapes and lines required by the motor vehicle manufacturer.

In order to produce the metalized portions, use is generally made of machines for metalization under vacuum by evaporation, or machines for metalization under vacuum by sputtering.

To avoid the metalization of an entire part, covers or screen-forming parts are produced to prevent the metalization of certain portions.

Those skilled in the art refer to these non-metalized portions protected by covers or screen-forming parts using the expression “resists”.

The production of the resists makes it possible to prevent the metalization on a particular zone of a part in order to obtain an aspect or an appearance that produces a contrast effect between the metalized and non-metalized surfaces.

The production of the resists is carried out using metal covers with flexible resin contours on the zones of the plastic part that must not be metalized.

These known arrangements have however the drawbacks of a significant space requirement in the metalization chambers and of an increase in the cycle time of the total process.

Moreover, in order to guarantee a good finish of the products, it is necessary to provide recesses or shoulders on the parts, in order to ensure a good attachment of the metal covers and flexible resin parts protecting the surfaces that must not be metalized.

The fact of producing recesses and shoulders however generates an undesirable aesthetic effect that motor vehicle manufacturers do not like.

Furthermore, the current process for producing the resists provides insufficient accuracy, of the order of a millimeter, which is not suitable for the production of top of the range parts.

In addition, the limitations due to the poor accuracy of the current technique sometimes make it necessary to assemble several parts in order to avoid the unaesthetic effects, which further lengthens the total production cycle time.

In the case of systems using flexible material covers, the injection-molded parts run the risk of yellowing during the metalization transition. This yellowing is due to the high degree of degassing of the flexible materials, which are generally based on silicones. In order to reduce or prevent the undesirable degassing of the silicone-based flexible materials, it is necessary to increase the pumping times in order to create a higher vacuum in the metalization chambers, which further increases the production cycle time.

The use of a cover requires additional process steps which considerably slow down the manufacture of such parts. Specifically, the cover is contaminated after a certain number of uses, and must be changed periodically. Furthermore, a change of the design of the various zones requires a change of cover, and therefore a relatively long interruption of the production line.

Furthermore, since the cover has a non-zero thickness, it results therefrom that the edges of the non-metalized zones are usually not the exact reproduction of the edges of the cover used, and may be more or less blurred or more or less rectilinear.

Other processes are known for producing a selective metalization of parts, which consist in entirely metalizing the surface of the part then in selectively removing this metalized layer in order to obtain the desired aesthetic effect.

According to a first known process, the whole of the surface of the part is metalized, then a cover is positioned on the metalized part, then the portions of the part not protected by the cover are etched so as to selectively remove the metalization, then the cover is removed, in the manner of the manufacture of circuits printed by exposure to light. The etching may be chemical or mechanical, by sandblasting in particular. Chemical etching has the effect of leading to a discoloration of the metal at the edge of the metalized zone. Etching by sandblasting will remove the metal layer but will also affect the surface appearance of the part, creating a texturing which is not generally aesthetically desired: specifically, an appearance that is smooth and/or with a controlled texturing (grained or leather appearance for example) of the non-metalized surface is preferred by motor vehicle manufacturers.

According to another known process, the metalization layer is selectively removed by laser ablation. This technique makes it possible to obtain a very great fineness of the metalization patterns, with non-metalized zones that may be less than 5 mm wide, impossible to obtain with the techniques of covering or masking the selected zones. In addition, the edge of the metalized zone is sharp and without discolorations. Although to the naked eye the surface of the part bared by ablation no longer has a trace of the metal coating, spectroscopic analysis shows residual traces of the metal; in addition, microscopic examination of the surface reveals the traces of impact of the laser radiation on the surface of the part. Although the process with laser ablation makes it possible to obtain precise metalization edges, it has the drawback of requiring a long production time, which is a function of the area of the metalized surface to be swept by the laser beam. It is therefore generally reserved for small surfaces, of several tens of cm².

### SUMMARY OF THE INVENTION

A first objective of the invention is to provide a novel coating process for producing a selective metalization, comprising the deposition of a metalization layer, on a motor vehicle lighting and/or signaling device part, while overcoming the drawbacks of the known techniques.

A second objective of the invention is to provide a novel device for the coating in order to produce a selective metalization of a motor vehicle lighting and/or signaling device part that enables a reduction in the total cycle time for manufacturing a motor vehicle part.

A third objective of the invention is to provide a novel motor vehicle lighting and/or signaling device part that has metalized portions and non-metalized portions with improved manufacturing precision.

In this respect, one subject of the invention is a coating process for producing a selective metalization, comprising the deposition of a metalization layer, on a motor vehicle lighting and/or signaling device part intended to comprise metalized portions and non-metalized portions, wherein an application, prior to the metalization, of a covering film to the portions intended not to be metalized, so as to protect the portions intended not to be metalized during the vacuum metalization operation and so as to bare the non-metalized portions after removal of the covering film.

Within the meaning of the invention, the motor vehicle lighting and/or signaling device parts are rigid parts with a flexural modulus of greater than 1000 MPa. Preferably, these parts are made of plastic, of synthetic polymer type, and are injection molded.

In particular, these parts are headlamp or light masks, reflectors or plates, but also interior lighting or signaling device parts such as a display console, a ceiling light or a light dome.

The process according to the invention may also have, besides the main features stated in the preceding paragraph, one or more of the following complementary features:
The application of the covering film is automatic.
The covering film is produced by depositing a peelable material, namely that is capable of being peeled, such as an ink, a paint, a varnish, a foam or a thermoplastic material. The expression “peelable material” is understood in the present invention to mean that it has a certain adhesion to the surface on which it is deposited and that it is removable by tearing or pulling, the force needed to remove it from the surface on which it is applied being non-zero and preferably being less than 50 N, preferentially less than 5 N, measured according to the F test method of the ASTM D3330/D3330M-04(2010) standard entitled “Standard Test Method for Peel Adhesion of Pressure-Sensitive Tape”, a test method which measures the adhesive force, that is to say the force needed to tear off, with an angle of 90° with respect to the surface on which they are applied, 100 mm long strips of a given material.
The application of the covering film is carried out with the aid of a preheated pad or application head.
The pad or the application head is preheated to a temperature above the temperature generated by the vacuum metalization at the surface of the motor vehicle part.
The pad or the application head is preheated to a temperature between 65° C. and 180° C., preferably between 65° C. and 160° C.
The covering film advantageously comprises a heat sealing thermoplastic material that is peelable at ambient temperature, for example between 15° C. and 50° C.
The covering film is a thermoplastic film comprising a layer of polyurethane (PU) which is bought into contact with the surface of the part.
The thermoplastic material has a low degree of degassing under vacuum.
The covering film advantageously has a thickness of between 20 and 150 micrometers. Preferably, the thickness is between 20 and 80 micrometers, for example between 20 and 40 micrometers.
The film has a tensile strength of the order of 30 megapascals and a very high elongation at break, of the order of 450%.

Another subject of the invention is a coating device for producing a selective metalization, comprising the deposition of a metalization layer, on a motor vehicle lighting and/or signaling device part intended to comprise metalized portions and non-metalized portions, comprising means, especially automatic means, for applying a covering film to the portions intended not to be metalized, so as to protect the portions intended not to be metalized during the vacuum metalization operation and so as to bare the non-metalized portions after removal of the covering film.

The coating device according to the invention may also have, besides the main features stated in the preceding paragraphs, one or more of the following complementary features:
The covering film is produced by depositing a peelable material, such as an ink, a paint, a varnish, a foam or a thermoplastic material.
The means for applying the covering film comprise a pad or an application head.
The pad or the application head is capable of being preheated, for example to a temperature above the temperature generated by the vacuum metalization at the surface of the motor vehicle part.
The device comprises means for preheating the pad or the application head. These means may for example be a resistance heating plate or a heated metal sheet. It is also possible to use a laser.
The pad or application head has a shape complementary to the surface intended to be non-metalized on the part to be metalized; this makes it possible to deposit films on parts of complex geometry, especially with various curves and/or concavities.
The pad or application head is in this case advantageously deformable so as to closely fit non-planar parts.
The means for applying the covering film comprise a covering film winding means and unwinding means.
The device is arranged in order to implement the process according to the invention.

The invention finally relates to a motor vehicle lighting and/or signaling device part having metalized portions and non-metalized portions obtained by implementation of a process according to the invention or by use of a device according to the invention.

These and other objects and advantages of the invention will be apparent from the following description, the accompanying drawings and the appended claims.

### BRIEF DESCRIPTION OF THE ACCOMPANYING DRAWINGS

The invention will be better understood owing to the following description given by way of nonlimiting example, with reference to the appended drawings in which:

FIG. 1 schematically represents a flowchart for a coating process according to the invention; and

FIG. 2 schematically represents a coating device according to the invention.

### DETAILED DESCRIPTION OF THE PREFERRED EMBODIMENTS

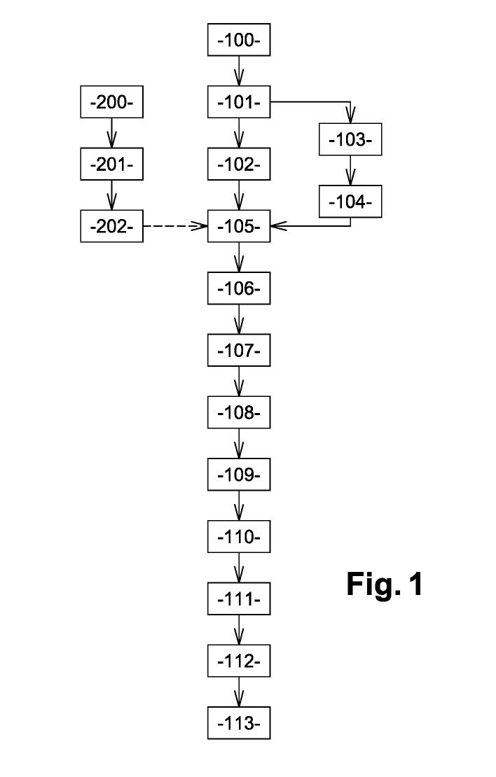

In FIG. 1, a coating process according to the invention, for depositing a metalization layer on a motor vehicle lighting and/or signaling device part 1 intended to comprise metalized portions and non-metalized portions, comprises main steps 100 to 113 and masked time steps 200 to 202.

The masked time steps 200 to 202 comprise: a step 200 of heating a system for depositing a covering film on a motor vehicle lighting and/or signaling device part 1, a step 201 of holding at temperature a pad or an application head 2 for depositing the system and a step 202 of bringing the pad or application head 2 preheated to the holding temperature of step 201 into contact with the covering film in order to apply to the motor vehicle lighting and/or signaling device part 1a covering film that corresponds to the contours of the pad or of the application head 2.

In step 100, a motor vehicle lighting and/or signaling device part 1 is injection molded in a manner known per se in a thermoplastic injection-molding machine.

In step 101, the motor vehicle lighting and/or signaling device part 1 or parts injection-molded in step 100 is (are) ejected in order to move it (them). In the case where the injection-molding machine is near the machine for depositing the covering film, the next step is step 102 of putting the injection-molded parts in place in the machine for depositing the covering film.

In the case where the injection-molding machines and the machines for depositing the covering film are further apart, the next step is step 103 of putting the injection-molded motor vehicle lighting and/or signaling device parts 1 onto a conveyor, then step 104 of putting the injection-molded vehicle lighting and/or signaling device parts 1 in place in the machine for depositing the covering film, for example manually.

Irrespective of the configuration of the equipment, the next step is a step 105 of lowering a pad or an application head 2 in order to apply the covering film to the injection-molded motor vehicle lighting and/or signaling device part 1.

Preferably, the covering film is mounted on a support capable of being wound or unwound, so that the lowering of the pad or of the application head 2 carries out a partial cutting of the covering film surface intended to be applied to the motor vehicle lighting and/or signaling device part 1.

Preferably, the covering film is a thermoplastic film comprising a layer of polyurethane (PU) which is brought into contact with the surface of the motor vehicle lighting and/or signaling device part 1.

After having held the pad or the application head 2 for a duration of the order of five seconds, the pad or the application head 2 is raised back up in step 106, having thus carried out an application of the covering film to the portions of the motor vehicle lighting and/or signaling device part 1 which must not be metalized.

This application thus makes it possible to obtain a motor vehicle lighting and/or signaling device part 1 that is ready to be metalized along defined contours with an accuracy of the order of 2/10th of a millimeter.

Due to the adhesion of the covering film to the motor vehicle lighting and/or signaling device part 1, the parts prepared by coating with the covering film require no additional protection or cover, before moving on to the metalization operation.

The temperature for positioning the covering film is preferably significantly higher than the temperature to which the motor vehicle lighting and/or signaling device part 1 will be subjected by the vacuum metalization operation.

The temperatures generated on the motor vehicle lighting and/or signaling device parts 1 by vacuum metalization operations are of the order of 50° C. to 60° C., whereas the temperature for deposition of covering film by the pad or the application head 2 is higher than the metalization temperature and is between (limits included) 65° C. and 180° C., preferably between 65° C. or 70° C. and 160° C., more preferably between 65° C. or 70° C. and 120° C. This temperature is preferably above 100° C., for example of the order of 120° C. and preferably remains below 125° C.

The vacuum metalization machines are for example sputtering machines or other machines for metal evaporation under vacuum.

In step 107, the vehicle lighting and/or signaling device parts 1 prepared are put in place on a conveyor, headed for the metalization machines.

In step 108, the motor vehicle lighting and/or signaling device parts 1 prepared having their surface protected by covering film are put in place in the vacuum metalization machines.

In step 109, the vacuum metalization is carried out on the motor vehicle lighting and/or signaling device part 1 having surfaces protected by covering film.

In step 110, the metalized motor vehicle lighting and/or signaling device parts 1 are extracted from the vacuum metalization machines, for example manually.

In step 111, the surface-metalized covering films are removed by peeling or by any other means for baring the non-metalized surfaces of the motor vehicle lighting and/or signaling device part 1.

In step 112, the partially and selectively metalized motor vehicle lighting and/or signaling device part 1 is optionally assembled with a screen or a sealing outer lens, especially in the case of a motor vehicle headlamp or light.

In step 113, the vehicle lighting and/or signaling device parts 1 or the finished motor vehicle lighting and/or signaling devices are extracted, headed for packaging and storage with the intention of sending to a motor vehicle manufacturer.

The invention described with reference to this particular coating process is in no way limited thereto, but also covers any production of covering film by deposition of a peelable material, such as an ink, a foam or a thermoplastic material.

Preferably, the use of a thermoplastic material is carried out by incorporating this thermoplastic material into a strip capable of being wound and unwound, and the support of which enables the application of the pad or the application head 2 heated to a temperature above the temperature generated by the vacuum metalization, so as to define a portion of covering film corresponding to the portions intended not to be metalized.

The invention also extends to the cases of separate or successive covering films, in the case of successive metalizations bearing various colors.

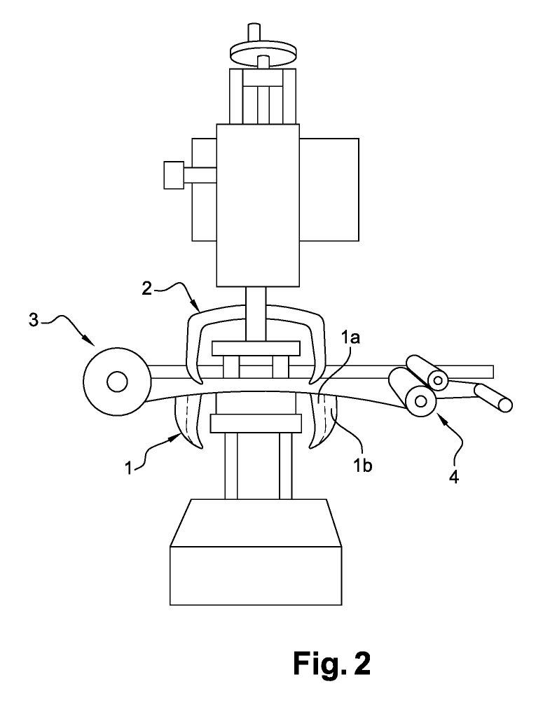

In FIG. 2, a coating device for depositing a metalization layer on a motor vehicle lighting and/or signaling device part 1 is intended to define non-metalized portions to be covered by a covering film.

Those skilled in the art use the word “resist” to refer to the portions of the plastic parts intended not to be metalized.

The production of the resists 1a makes it possible to prevent the metalization on the protected zones of a motor vehicle lighting and/or signaling device part 1 in order to obtain the desired style effect between the surface to be metalized 1b and the surfaces which are resist-coated, called resists 1a.

The placement of the covering films at the locations corresponding to the resists 1a is preferably carried out by lowering a pad or application head 2 which is preheated for example to a temperature of the order of 100° C., to a temperature above the temperature to which the motor vehicle lighting and/or signaling parts 1 will be brought by the metalization operation.

The covering film is preferably spread over the lower face of a two-layer strip wound in the form of a roll 3 and unwound by suitable means in order to run under the application head 2.

The pad or application head 2 is then applied at the required preheated temperature to the two-layer film so as to detach a portion of the lower layer of the two-layer strip in order to apply it to the motor vehicle lighting and/or signaling device part 1 to be metalized.

The lower portion applied by the pad or application head 2 to the motor vehicle lighting and/or signaling device part 1 corresponds to the contours of the pad or application head 2, and is detached by adhesion, creating a clean break between the lower surface of the roll 3 of two-layer strip, owing to the effect of adhesion to the motor vehicle lighting and/or signaling device part 1 due to the application of the pad or application head 2 in contact with the motor vehicle lighting and/or signaling device part 1.

The roll 3 of two-layer strip is then wound onto a second roll 4 of two-layer strip, portions of which have been applied to the motor vehicle lighting and/or signaling device parts 1, by a “thermal stamping” effect giving a clear definition of the edges with an accuracy of the order of 2/10th of a millimeter.

Preferably, the two-layer strip comprises a support layer made from a material of polyethylene type, whereas the layer intended to be applied in contact with the motor vehicle lighting and/or signaling device part 1 in order to form the resists 1a is a layer of a different material, easily peelable at low temperature, for example a polyurethane.

Tests have shown that the application of the covering films may be carried out preferably so as to define, in contact with the part, a thickness of between 20 and 150 micrometers, especially between 20 and 80 micrometers, and more particularly between 20 and 40 micrometers, using an application temperature above 65° C. and especially between 100° C. and 160° C., especially for a duration of the order of one to several minutes.

The tests showed that the films thus defined are satisfactory and avoid the drawbacks of the prior art, especially the degassings that may result in blurred boundaries or color defects during the metalization.

The tests also showed that the removal of the covering film by peeling is easy and leaves no trace on the portion corresponding to the resists 1a.

The films that are particularly suitable for the implementation of the invention preferably have a low degree of degassing.

The films that are particularly suitable for the implementation of the invention preferably have a high tensile strength, of the order of 30 megapascals, and a very high elongation at break, of the order of 450%.

The flexural strain characteristic of the films used for the implementation of the invention is a very high flexural strain, so as to place resists 1a in complex conformations, especially while enabling an application depth of the order of 150 millimeters.

The invention described with reference to one particular embodiment is in no way limited thereto, but on the contrary covers any shape modification and any embodiment variant within the context and spirit of the appended claims.

Thus, instead of applying a film that is part of a two-layer strip, it is also possible to apply a film that is part of a strip having a higher number of layers, for example a three-layer strip.

In this case, the intermediate layer may have an additional barrier role in order to guarantee the good homogeneity of the film deposited on the motor vehicle lighting and/or signaling device part 1.

Also, other materials may be used, such as an ink or a foam for positioning on a motor vehicle lighting and/or signaling device part 1, by means of an optional modification of the pad or application head 2 of the coating device according to the invention.

Generally, the covering film is formed from a material that has characteristics that enable a reversible adhesion. In particular, this material forming it adheres under given adhesion conditions and no longer adheres under given non-adhesion conditions.

In the case of a deposition of a film by application of a preheated pad or application head 2, these are thermal conditions, as was stated above. Thus, at 100° C. the film is subjected to these adhesion conditions, and on dropping to 90° C., this film is subjected to its non-adhesion conditions, then enabling the peeling. An even more efficient peeling is obtained by dropping to or below 50° C. However, techniques other than the deposition of a film by application of a preheated pad or application head 2 may be used.

For example, it is possible to use methods in which the material forming the covering film adheres as a function of electrostatic conditions.

According to another example of a deposition method, the covering film may be an adhesive film, for example under certain pressure conditions. The process then uses a pad or application head 2, by means of which a sufficient pressure is applied to attain the adhesion conditions of the material. After the deposition, since the pressure is no longer applied, the material is therefore subjected to its non-adhesion conditions. It may then be easily removed by peeling. It is possible according to certain examples to use a pad or application head 2 without preheating, the adhesion taking place only by pressure. Other methods may use a combination of heating and application of pressure.

Owing to the invention, the novel coating process for the deposition of a metalization layer on a motor vehicle lighting and/or signaling device part 1 makes it possible to increase the productivity, to be adapted to a production line and to provide an accuracy of the boundary between metalized and non-metalized portions of the order of 0.2 millimeter with respect to the nominal boundary or better than 0.2 millimeter (i.e. an accuracy range of 0.4 mm or less).

The fact of automatically producing the resists 1a owing to the process according to the invention also makes it possible to do away with the silicone-edged metal covers of the prior art, which prevented the correct filling of the vacuum metalization machines.

One advantage of the invention is to increase the productivity of the metalization lines by making it possible not only to produce several resists 1a on one and the same motor vehicle lighting and/or signaling device part 1, but also to automate the production by integrating the automatic production of the resists 1a into the production line.

In addition, motor vehicle lighting and/or signaling device parts 1 are obtained in which the boundary of the metalized zones is sharp and has no color change or gradation in the vicinity of these boundaries. Furthermore, the surface of the motor vehicle lighting and/or signaling device part 1 which is not metalized is free of traces of sandblasting or laser texturing and has no residual traces of metalization since the non-metalized surface has not been coated with an initial metalization layer.

Thus, a step of metalized material is observed at the boundary with a slope of less than or equal to 2° and a virtually rectilinear transition. The transition from metalized layer to non-metalized surface of the part is abrupt and substantially uniform for the whole of the boundary. The transition profile at the boundary is established by measuring the thickness of the metal layer which is determined by local conductimetry measurement.

The peeling of the covering films of the resists 1a may be carried out manually or automatically, for example by suction or by an electrostatic effect, or else by laser ablation.

The invention described with reference to several embodiments is in no way limited thereto, but on the contrary covers any shape modification and any embodiment variant within the context of the appended claims.

Thus, although the invention describes an automatic application of a covering film to the portions intended not to be metalized, the invention also extends to a manual application of a covering film to the portions intended not to be metalized, so as to protect the portions intended not to be metalized during the vacuum metalization operation and so as to bare the non-metalized portions after removal of the covering film.

While the system, apparatus, process and method herein described constitute preferred embodiments of this invention, it is to be understood that the invention is not limited to this precise system, apparatus, process and method, and that changes may be made therein without departing from the scope of the invention which is defined in the appended claims.

What is claimed is:

1. A coating process for producing a selective metalization, comprising the steps of deposition of a metalization layer, on a motor vehicle lighting and/or signaling device part intended to comprise metalized portions and non-metalized portions, wherein an application, prior to said metalization, of a covering film to said portions intended not to be metalized, so as to protect said portions intended not to be metalized during a vacuum metalization operation and so as to bare said non-metalized portions after removal of said covering film.

2. The coating process as claimed in claim 1, wherein said covering film is produced by depositing a peelable material, such as an ink, a foam, a paint, a varnish or a thermoplastic material.

3. The coating process as claimed in claim 1 wherein said application of said covering film is carried out with the aid of a pad or a printing head.

4. The coating process as claimed in claim 3, wherein said pad or said printing head is preheated.

5. The coating process as claimed in claim 4, wherein said pad or said printing head is preheated to a temperature above the temperature generated by said vacuum metalization operation at the surface of said motor vehicle lighting and/or signaling device part.

6. The coating process as claimed in claim 5, wherein said pad or said printing head is preheated to a temperature between 65° C. and 180° C., preferably between 65° C. and 160° C.

7. The coating process as claimed in claim 1, wherein said covering film comprises a heat sealing thermoplastic material that is peelable at ambient temperature.

8. The coating process as claimed in claim 1, wherein said covering film has a thickness of between 20 and 150 micrometers.

9. The coating process as claimed in claim 1, wherein said covering film has a tensile strength of the order of 30 megapascals and a very high elongation at break, of the order of 450%.

10. A coating device for the deposition of a metalization layer on a motor vehicle lighting and/or signaling device part intended to comprise metalized portions and non-metalized portions, comprising means for applying a covering film to said portions intended not to be metalized, so as to protect said portions intended not to be metalized during a vacuum metalization operation and so as to bare said non-metalized portions after removal of said covering film.

11. The coating device as claimed in claim 10, wherein said covering film is produced by depositing a peelable material, such as an ink, a foam, a paint, a varnish or a thermoplastic material.

12. The coating device as claimed in claim 11, wherein the means for applying said covering film comprise a pad or an application head.

13. The coating device as claimed in claim 12, wherein said pad or said application head is capable of being preheated.

14. The coating device as claimed in claim 13, wherein said pad or said application head is capable of being preheated to a temperature above the temperature generated by said vacuum metalization at the surface of said motor vehicle lighting and/or signalling device part.

15. The coating device as claimed in claim 12, wherein said coating device comprises means for preheating said pad or said application head.

16. The coating device as claimed in claim 10, wherein said means for applying said covering film comprise a covering film winding means and unwinding means.

17. The coating device as claimed in claim 10, wherein said coating device is arranged so as to be able to implement a coating process for producing a selective metalization, comprising the steps of deposition of a metalization layer, on a motor vehicle lighting and/or signaling device part intended to comprise metalized portions and non-metalized portions, wherein an application, prior to said metalization, of a covering film to said portions intended not to be metalized, so as to protect said portions intended not to be metalized during a vacuum metalization operation and so as to bare said non-metalized portions after removal of said covering film.

18. A motor vehicle lighting and/or signaling device part having metalized portions and non-metalized portions obtained by implementation of said coating process as claimed in claim 1.

19. A coating process for producing a selective metalization on a motor vehicle lighting and/or signaling device part intended to comprise metalized portions and non-metalized portions, comprising the steps of:
depositing a metalization layer on the motor vehicle lighting and/or signaling device part intended to comprise metalized portions and non-metalized portions; and
prior to said metalization, applying a covering film to said non-metalized portions intended not to be metalized, so as to protect said non-metalized portions intended not to be metalized during a vacuum metalization operation and so as to bare said non-metalized portions after removal of said covering film.

20. The coating process as claimed in claim 19, wherein said covering film is produced by depositing a peelable material, such as an ink, a foam, a paint, a varnish or a thermoplastic material.
